(19) United States
(12) Patent Application Publication
(10) Pub. No.: US 2025/0301802 A1
(43) Pub. Date: Sep. 25, 2025

(54) CURVED PHOTOVOLTAIC MODULE

(71) Applicant: SHENZHEN HELLO TECH ENERGY CO., LTD, Shenzhen (CN)

(72) Inventors: Yanjun ZHU, Shenzhen (CN); Zhongwei SUN, Shenzhen (CN)

(21) Appl. No.: 19/230,143

(22) Filed: Jun. 6, 2025

Related U.S. Application Data
(63) Continuation of application No. PCT/CN2025/070200, filed on Jan. 2, 2025.

(30) Foreign Application Priority Data
Feb. 26, 2024 (CN) 202410214118.8
Feb. 26, 2024 (CN) 202420353654.1
Jun. 7, 2024 (CN) 202410737806.2

(51) Int. Cl. H10F 19/80

(52) U.S. Cl. CPC H10F 19/807; H10F 19/804

(57) ABSTRACT

Provided is a curved photovoltaic module. The curved photovoltaic module includes a solar cell unit, and curved glass and a curved back panel that are disposed at both sides of the solar cell unit. A first encapsulant film layer is arranged between the curved glass and the solar cell unit. A second encapsulant film layer is arranged between the curved back panel and the solar cell unit. The first encapsulant film layer has a thickness ranging from 0.8 mm to 2 mm. The second encapsulant film layer has a thickness ranging from 0.8 mm to 2 mm.

### CROSS-REFERENCE TO RELATED APPLICATION

This application is a continuation of International Application No. PCT/CN2025/070200, filed on Jan. 2, 2025, which claims priorities to and benefits of Chinese patent application No. 202410737806.2, filed with China National Intellectual Property Administration on Jun. 7, 2024, Chinese patent application No. 202410214118.8, filed with China National Intellectual Property Administration on Feb. 26, 2024, and Chinese patent application No. 202420353654.1, filed with China National Intellectual Property Administration on Feb. 26, 2024, the entire contents of which are incorporated herein by reference.

### FIELD

The present disclosure relates to the field of battery technologies, and more particularly, to a curved photovoltaic module.

### BACKGROUND

Curved photovoltaic products, due to their unique design and flexibility, are widely used in various occasions, including roof power generation tiles, car roofs, and irregular-shaped buildings. Early curved photovoltaic products used thin-film technology, which had the disadvantages of low conversion efficiency and high cost. Recently, crystalline silicon solar cell technology has developed rapidly, and the power generation efficiency has been improved continuously. Researching crystalline silicon solar cell bending technology and developing a curved encapsulation process for crystalline silicon solar cells are effective ways to improve curved photovoltaic products.

Due to the brittleness of the crystalline silicon solar cell and its extremely thin thickness, when the solar cell is bent, the stress and deformation at various positions such as an edge and a center are different. The displacement deviation caused by the uneven deformation leads to hard contact between a local part of the solar cell and glass or a back panel, resulting in the fragmentation of the solar cell.

Therefore, it is urgent to propose a curved photovoltaic module that can prevent the occurrence of hidden cracks or even fragmentation caused by uneven deformation when the solar cell is bent.

### SUMMARY

An objective of the present disclosure is to provide a curved photovoltaic module, which can not only disperse the stress concentration when a solar cell unit is bent, but also prevent the occurrence of hidden cracks or even fragmentation caused by hard contact between a position with large local deformation of the solar cell unit and glass or a back panel when the bending deformation of the solar cell unit is uneven.

To achieve this objective, the present disclosure adopts the following technical solutions.

The present disclosure provides a curved photovoltaic module including a solar cell unit, and curved glass and a curved back panel that are disposed at two sides of the solar cell unit. A first encapsulant film layer is arranged between the curved glass and the solar cell unit. A second encapsulant film layer is arranged between the curved back panel and the solar cell unit. The first encapsulant film layer has a thickness ranging from 0.8 mm to 2 mm. The second encapsulant film layer has a thickness ranging from 0.8 mm to 2 mm.

In some embodiments, the curved back panel has a thickness ranging from 0.35 mm to 0.7 mm. The curved glass has a thickness ranging from 3 mm to 5 mm.

In some embodiments, the curved back panel is a semi-rigid material layer, and is a PET layer or a glass fiber material layer.

In some embodiments, the curved back panel includes a main body layer and an encapsulation material layer arranged at each of both sides of the main body layer. The main body layer has a greater thickness than the encapsulation material layer.

In some embodiments, the first encapsulant film layer includes at least one selected from the group consisting of an EVA encapsulant film, a POE encapsulant film, an EPE encapsulant film, and a PVB encapsulant film; and/or the second encapsulant film layer includes at least one selected from the group consisting of an EVA encapsulant film, a POE encapsulant film, an EPE encapsulant film, and a PVB encapsulant film.

In some embodiments, the solar cell unit includes a plurality of solar cells, each of the plurality of solar cells has a bending radius ranging from 25 mm to 200 mm.

In some embodiments, a longitudinal projection of each of the curved back panel and the curved glass is a curve composed of a curve segment; or a longitudinal projection of each of the curved back panel and the curved glass is a curve composed of a plurality of curve segments connected in sequence; or a longitudinal projection of each of the curved back panel and the curved glass is an irregular curve composed of a curve segment and a straight segment. The curve segment is in an arc shape. A ratio of an arc length to a corresponding chord length of the curve segment ranges from 1.03 to 1.67.

In some specific embodiments, the longitudinal projection of the curved back panel includes a plurality of first peaks and a plurality of first valleys that are arranged alternately. The longitudinal projection of the curved glass includes a plurality of second peaks and a plurality of second valleys that are arranged alternately. The plurality of first peaks are aligned with the plurality of second peaks, respectively. The plurality of first valleys are aligned with the plurality of second valleys, respectively.

In some more specific embodiments, the solar cell unit includes a plurality of solar cells electrically connected to each other. A part of each of the plurality of solar cells is located between a corresponding first peak of the plurality of first peaks and a corresponding second peak of the plurality of second peaks, and the other part of each of the plurality of solar cells is located between a corresponding first valley of the plurality of first valleys and a corresponding second valley of the plurality of second valleys.

In some embodiments, the thickness of the first encapsulant film layer is greater than that of the second encapsulant film layer.

Beneficial effects of the curved photovoltaic module of the present disclosure are as follows. Since the first encapsulant film layer with the thickness ranging from 0.8 mm to 2 mm is added between the curved glass and the solar cell unit, and the second encapsulant film layer with the thickness ranging from 0.8 mm to 2 mm is added between the curved back panel and the solar cell unit, the first encapsulant film layer and the second encapsulant film layer, serving as adhesive bonding layers between the solar cell unit and the curved glass or the curved back panel, can ensure structural reliability of the curved photovoltaic module, preventing the curved glass and the curved back panel from falling off relative to the solar cell unit. In addition, the first encapsulant film layer and the second encapsulant film layer, also serving as buffer layers with sufficient thickness, on the one hand, disperse the stress concentration when a rigid solar cell unit is bent, and on the other hand, avoid hard contact between a position with large local deformation of the solar cell unit and the curved glass or the curved back panel when the bending deformation of the solar cell unit is uneven, preventing the occurrence of hidden cracks or even fragmentation.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic exploded structural view of a curved photovoltaic module according to the present disclosure.

FIG. 2 is a schematic vertical cross-sectional view showing a back panel structure of a curved photovoltaic module according to the present disclosure.

### REFERENCE NUMERALS OF THE ACCOMPANYING DRAWINGS

100, curved glass; 110, first peak; 120, first valley;
200, first encapsulant film layer;
300, solar cell unit;
400, second encapsulant film layer;
500, back panel; 510, main body layer; 520, encapsulation material layer; 530, second peak; 540, second valley.

### DETAILED DESCRIPTION OF THE EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

A number of embodiments or examples are provided in the disclosure of the present disclosure to implement different structures of the embodiments of the present disclosure. To simplify the disclosure of the embodiments of the present disclosure, components and arrangements of particular examples will be described below, which are, of course, examples only and are not intended to limit the present disclosure. Further, reference numerals and/or reference letters may be repeated in different examples of the embodiments of the present disclosure. Such repetition is for the purpose of simplicity and clarity and does not indicate any relationship between various embodiments and/or arrangements in question. In addition, various examples of specific processes and materials are provided in the embodiments of the present disclosure. However, those of ordinary skill in the art may be aware of applications of other processes and/or the use of other materials.

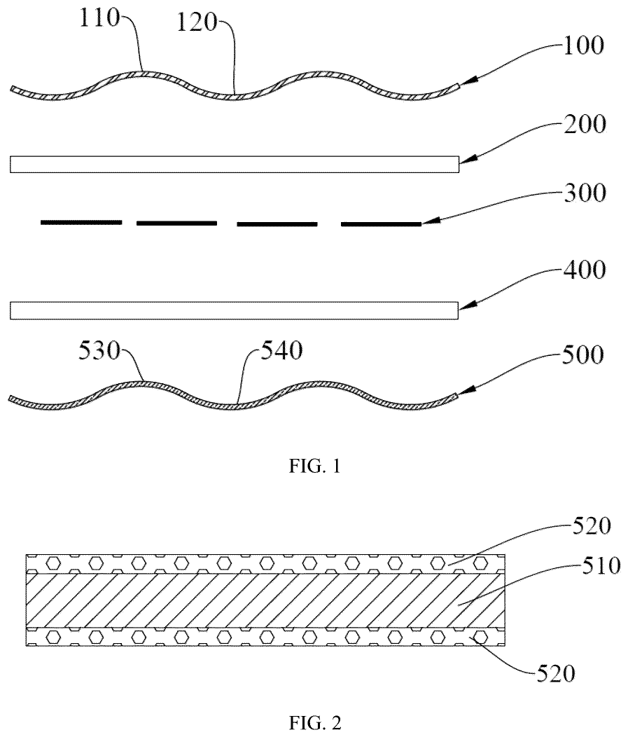

The present disclosure provides a curved photovoltaic module. As illustrated in FIG. 1, the curved photovoltaic module in the present embodiment includes a solar cell unit 300, and curved glass 100 and a curved back panel 500 that are disposed at two sides of the solar cell unit 300. A first encapsulant film layer 200 is arranged between the curved glass 100 and the solar cell unit 300. A second encapsulant film layer 400 is arranged between the curved back panel 500 and the solar cell unit 300. The first encapsulant film layer has a thickness ranging from 0.8 mm to 2 mm, and the second encapsulant film layer has a thickness ranging from 0.8 mm to 2 mm. It should be understood that, the first encapsulant film layer 200 with the thickness ranging from 0.8 mm to 2 mm is added between the curved glass 100 and the solar cell unit 300, and the second encapsulant film layer 400 with the thickness ranging from 0.8 mm to 2 mm is added between the curved back panel 500 and the solar cell unit 300. The first encapsulant film layer 200 and the second encapsulant film layer 400, serving as adhesive bonding layers between the solar cell unit 300 and the curved glass 100 or the curved back panel 500, can ensure structural reliability of the curved photovoltaic module, preventing the curved glass 100 and the curved back panel 500 from falling off relative to the solar cell unit 300. It should be noted that, an adhesive material used in an industrial-grade planar photovoltaic module has a thickness ranging from 0.4 mm to 0.6 mm, which can meet requirements when the solar cell is planar. However, when the solar cell is bent, stress and deformation at various positions such as an edge and a center are different. Sufficient filling materials are needed to make up for displacement deviation caused by uneven deformation and to avoid hard contact between a local part of the solar cell and the glass or the back panel. Therefore, the adhesive material used in the existing industrial-grade planar photovoltaic module is unable to be applied to the curved photovoltaic module. In the present embodiment, the first encapsulant film layer 200 and the second encapsulant film layer 400, serving as buffer layers with sufficient thickness, on the one hand, disperse the stress concentration when a rigid solar cell unit 300 is bent, and on the other hand, avoid hard contact between a position with large local deformation of the solar cell unit 300 and the curved glass 100 or the curved back panel 500 when the bending deformation of the solar cell unit 300 is uneven, preventing the occurrence of hidden cracks or even fragmentation.

Optionally, the thickness of the first encapsulant film layer 200 is 0.8 mm, 0.9 mm, 1.0 mm, 1.1 mm, 1.2 mm, 1.3 mm, 1.4 mm, 1.5 mm, 1.6 mm, 1.7 mm, 1.8 mm, 1.9 mm, or 2.0 mm. Of course, in other embodiments of the present disclosure, the thickness of the first encapsulant film layer 200 may be selected from any value between 0.8 mm and 2 mm according to the thickness of the solar cell unit 300 and the curved glass 100, and is not limited to the above examples.

Optionally, the thickness of the second encapsulant film layer 400 is 0.8 mm, 0.9 mm, 1.0 mm, 1.1 mm, 1.2 mm, 1.3 mm, 1.4 mm, 1.5 mm, 1.6 mm, 1.7 mm, 1.8 mm, 1.9 mm, or 2.0 mm. Of course, in other embodiments of the present disclosure, the thickness of the second encapsulant film layer 400 may be selected from any value between 0.8 mm and 2 mm according to the thickness of the solar cell unit 300 and the curved back panel 500, and is not limited to the above examples.

It should be noted that, a relationship between the thickness of the first encapsulant film layer 200 and the thickness of the second encapsulant film layer 400 may be selected as desired. It should be understood that, in an actual operating process, the first encapsulant film layer 200 can absorb impact energy, and can play a buffering and protective role when the solar cell unit 300 is bent, to avoid the fragmentation caused by the hard contact between the solar cell unit 300 and the curved glass 100. The second encapsulant film layer 400 can absorb the impact energy transmitted from the curved back panel 500 and protect the solar cell unit 300 from cracking. Therefore, when the stress generated during bending of the solar cell unit 300 in a manufacturing process is relatively larger, and the impact energy transmitted from the back panel 500 in an actual use process is smaller, the thickness of the first encapsulant film layer 200 may be greater than that of the second encapsulant film layer 400. When the stress generated during the bending of the solar cell unit 300 in the manufacturing process is relatively smaller, and the impact energy transmitted from the back panel 500 in the actual use process is larger, the thickness of the first encapsulant film layer 200 may be smaller than that of the second encapsulant film layer 400. When the stress generated during the bending of the solar cell unit 300 in the manufacturing process is moderate, and the impact energy transmitted from the back panel 500 in the actual use process is also relatively moderate, the thickness of the first encapsulant film layer 200 may also be equal to that of the second encapsulant film layer 400. That is, in the actual manufacturing and production process, the thicknesses of the first encapsulant film layer 200 and the second encapsulant film layer 400 may be adjusted according to manufacturing processes and the specific usage scenarios.

In some embodiments, the curved back panel 500 has the thickness ranging from 0.35 mm to 0.7 mm. Compared with the back panel of the planar photovoltaic module with a thickness ranging from 0.25 mm to 0.35 mm, the thickness of the curved back panel 500 in the present embodiment is relatively larger, which allows the curved photovoltaic module in the present embodiment to better withstand the impact energy from a direction of the curved back panel 500, facilitating to improving reliability of an entire curved photovoltaic module.

Optionally, the thickness of the curved back panel 500 is 0.35 mm, 0.4 mm, 0.45 mm, 0.5 mm, 0.55 mm, 0.6 mm, 0.65 mm, or 0.7 mm. Of course, in other embodiments of the present disclosure, the thickness of the curved back panel 500 may also be any value between 0.35 mm and 0.7 mm as desired, and is not limited to the above examples.

In some embodiments, a longitudinal projection of each of the curved back panel 500 and the curved glass 100 is a curve composed of a plurality of curve segments connected in sequence. Specifically, as illustrated in FIG. 1, the longitudinal projection of the curved back panel 500 includes a plurality of first peaks 110 and a plurality of first valleys 120 that are arranged alternately, and the longitudinal projection of the curved glass 100 includes a plurality of second peaks 530 and a plurality of second valleys 540 that are arranged alternately. It should be understood that, since the longitudinal projection of the curved back panel 500 includes the plurality of first peaks 110 and the plurality of first valleys 120 that are arranged alternately, and the longitudinal projection of the curved glass 100 includes the plurality of second peaks 530 and the plurality of second valleys 540 that are arranged alternately, both the curved back panel 500 and the curved glass 100 are formed into wavy structures. Such a structure allows the curved glass 100 and the curved back panel 500 to be fitted with each other easily when they are processed in a stacked manner, which reduces processing difficulty of the curved photovoltaic module, facilitating to improving manufacturing yield of the curved photovoltaic module.

Further, the first peak 110 is aligned with the second peak 530, and the first valley 120 is aligned with the second valley 540. In this way, when the curved glass 100 and the curved back panel 500 are fitted with each other, protruding parts of the curved glass 100 are arranged corresponding to protruding parts of the curved back panel 500, and recessed parts of the curved glass 100 are arranged corresponding to recessed parts of the curved back panel 500. Such a structure allows the curved glass 100 and the curved back panel 500 to be fitted with each other more easily when they are processed in the stacked manner, reducing the processing difficulty of the curved photovoltaic module.

Further, the first peak 110 has the same curvature as the second peak 530, and the first valley 120 has the same curvature as the second valley 540. In this way, the longitudinal projections of the curved glass 100 and the curved back panel 500 are exactly the same. Such a structure allows the curved glass 100 and the curved back panel 500 to be fitted with each other more easily when they are processed in the stacked manner. Also, the curved glass 100 and the curved back panel 500 can be fitted with each other completely, i.e., 100% fitting can be achieved. Therefore, the processing difficulty of the curved photovoltaic module is reduced, and it is also conducive to improving processing accuracy of the curved photovoltaic module, enhancing finished product quality of the curved photovoltaic module.

Optionally, both the first peak 110 and the second peak 530 are in an arc shape, a ratio of an arc length to a corresponding chord length of the first peak 110 ranges from 1.03 to 1.67, and a ratio of an arc length to a corresponding chord length of the second peak 530 ranges from 1.03 to 1.67. In this way, the processing difficulty of the curved photovoltaic module can be further reduced, and it is also beneficial to improving the processing accuracy of the curved photovoltaic module, enhancing the finished product quality of the curved photovoltaic module.

In some embodiments, the solar cell unit 300 includes a plurality of solar cells electrically connected to each other. A part of each of the plurality of solar cells is located between the first peak 110 and the second peak 530, and the other part of each of the plurality of solar cells is located between the first valley 120 and the second valley 540. It should be understood that, if among the plurality of solar cells, some of the plurality of solar cells are completely located between the first peak 110 and the second peak 530, and other parts of the plurality of solar cells are completely located between the first valley 120 and the second valley 540, which results in that during stacked processing, the solar cells completely located between the first peak 110 and the second peak 530 are subjected to relatively greater pressure, and the solar cells located between the first valley 120 and the second valley 540 are subjected to relatively smaller pressure. Therefore, force deviation of an entire solar cell unit 300 is very large, which is not only unfavorable for the stacked processing, reducing the manufacturing yield, but also causes force conditions of each of the plurality of solar cells to be different, resulting in a larger power difference. In the present embodiment, the part of each of the plurality of solar cells is located between the first peak 110 and the second peak 530, and the other part of each of the plurality of solar cells is located between the first valley 120 and the second valley 540. Therefore, the force conditions of the plurality of solar cells are basically the same, which is not only conducive to the stacked processing, ensuring the manufacturing yield, but also enables the stress conditions of each of the plurality of solar cells to be the same, resulting in a smaller power difference.

Further, a length of each of the plurality of solar cells is equal to a spacing between a highest point of the first peak 110 and a lowest point of the first valley 120, and a midline of each of the plurality of solar cells is coincident with an inflection line between the first peak 110 and the first valley 120. Such an arrangement allows half of each of the plurality of solar cells to be located between the first peak 110 and the second peak 530, and another half of each of the plurality of solar cells to be located between the first valley 120 and the second valley 540.

Optionally, the solar cell unit 300 includes a plurality of solar cells, and each of the plurality of solar cells has a bending radius ranging from 25 mm to 200 mm. The bending radius of each of the plurality of solar cells may be 25 mm, 50 mm, 75 mm, 100 mm, 125 mm, 150 mm, 175 mm, or 200 mm. Of course, the bending radius of each of the plurality of solar cells may also be adjusted as desired. It should be understood that, each of the plurality of solar cells has the bending radius ranging from 25 mm to 200 mm, which can avoid the occurrence of insecure bonding due to too small a bending radius of the solar cell, and can also avoid the occurrence of solar cell cracking due to too large a bending radius of the solar cell.

In an alternative embodiment of the present disclosure, a longitudinal projection of each of the curved back panel 500 and the curved glass 100 is a curve composed of a curve segment. In another alternative embodiment, a longitudinal projection of each of the curved back panel 500 and the curved glass 100 is an irregular curve composed of a curve segment and a straight segment. Optionally, the curve segment is in an arc shape, and a ratio of an arc length to a corresponding chord length of the curve segment ranges from 1.03 to 1.67.

As illustrated in FIG. 2, the curved back panel 500 in the present embodiment includes a main body layer 510 and an encapsulation material layer 520 arranged at each of both sides of the main body layer 510. It should be understood that, the curved back panel 500 forms a sandwich-layer structure of encapsulation material layer 520-main body layer 510-encapsulation material layer 520, which, on the one hand, can ensure its strength and improve impact resistance of the curved photovoltaic module, and, on the other hand, can ensure its insulation properties and structural stability, avoiding the phenomenon of layer falling off.

Optionally, the main body layer 510 includes an aluminum plate, and the encapsulation material layer 520 includes a polyethylene terephthalate (PET) layer. It should be understood that, the aluminum plate is light in weight and has moderate deformation capacity. The PET layer has excellent electrical insulation, and its electrical performance remains good even under high temperature and high frequency. Also, the PET layer has good creep resistance, fatigue resistance, friction resistance, and dimensional stability. The curved back panel 500 is composed of a composite layer of the aluminum plate and the PET layer, which, on the one hand, can ensure its strength and improve the impact resistance of the curved photovoltaic module, and, on the other hand, can ensure complete electrical insulation between the curved photovoltaic module and an external plane in contact with the curved back panel 500, avoiding the occurrence of electric leakage. Of course, it should be noted that, in other embodiments of the present disclosure, the thicknesses of the main body layer 510 and the encapsulation material layer 520 may be adjusted as desired and are not limited to the above description.

In a specific embodiment, the thickness of the main body layer 510 is greater than that of the encapsulation material layer 520. The main body layer 510 is the aluminum plate with a thickness of 0.15 mm, and the encapsulation material layer 520 is the PET layer with a thickness of 0.1 mm. It should be understood that, the relatively thick main body layer 510 can ensure the strength of an entire curved back panel 500, and the relatively thin encapsulation material layer 520 can reduce the thickness of the entire curved back panel 500 while ensuring the insulation properties, which is conducive to lightweight design of the curved photovoltaic module. Of course, in other embodiments of the present disclosure, the thicknesses and relative relationships of the main body layer 510 and the encapsulation material layer 520 may be selected as desired and are not limited to the above description.

In an alternative embodiment, the curved back panel 500 is a semi-rigid material layer. It should be understood that, the curved back panel 500 is made of the semi-rigid material, which is a material that has both a rigid property and a flexible property. The flexible property can compensate for the tolerance and local thickness difference of the curved glass 100, the solar cell unit 300, and the curved back panel 500, and the rigid property can allow the curved back panel 500 to maintain a predetermined mechanical strength. When an external force is applied to press material layers together, the curved back panel 500 can evenly disperse and withstand the external force, greatly reducing an impact of pressing force on the solar cell unit 300. Also, the phenomenon of hidden cracks or even fragmentation of the solar cell unit 300 during a stacking process is avoided, which is conducive to improving the manufacturing yield of the curved photovoltaic module.

Optionally, the curved back panel 500 is a PET layer or a glass fiber material layer. Of course, in other alternative embodiments of the present disclosure, the material of the curved back panel 500 may also be selected as desired, and is not limited to the above limitations.

In some embodiments, the first encapsulant film layer 200 includes at least one selected from the group consisting of an ethylene-vinyl acetate copolymer (EVA) encapsulant film, a polyolefin elastomer (POE) encapsulant film, a co-extruded ethylene-vinyl acetate and polyolefin elastomer (EPE) encapsulant film (formed by physically co-extruding the EVA encapsulant film and the POE encapsulant film, combining excellent properties of both the POE encapsulant film and the EVA encapsulant film), and a polyvinyl butyral (PVB) encapsulant film. It should be further noted that, in some embodiments, the first encapsulant film layer 200 has a multi-layer composite structure. This multi-layer composite structure may include any two or more (more than two) of an EVA encapsulant film layer, a POE encapsulant film layer, an EPE encapsulant film layer, or a PVB encapsulant film layer. In some embodiments, the first encapsulant film layer 200 has a single-layer structure. This single-layer composite structure may be any one of the EVA encapsulant film layer, the POE encapsulant film layer, the EPE encapsulant film layer, or the PVB encapsulant film layer, or a single-layer structure made by mixing any two or more (more than two) of EVA, POE, EPE, or PVB.

In some embodiments, the second encapsulant film layer 400 includes at least one selected from the group consisting of an ethylene-vinyl acetate copolymer (EVA) encapsulant film, a polyolefin elastomer (POE) encapsulant film, an EPE encapsulant film (formed by physically co-extruding the EVA encapsulant film and the POE encapsulant film, combining the excellent properties of both the POE encapsulant film and the EVA encapsulant film), and a polyvinyl butyral (PVB) encapsulant film. It should be further noted that, in some embodiments, the second encapsulant film layer 400 has a multi-layer composite structure. This multi-layer composite structure may include any two or more (more than two) of an EVA encapsulant film layer, a POE encapsulant film layer, an EPE encapsulant film layer, or a PVB encapsulant film layer. In some embodiments, the second encapsulant film layer 400 has a single-layer structure. This single-layer composite structure may be any one of the EVA encapsulant film layer, the POE encapsulant film layer, the EPE encapsulant film layer, or the PVB encapsulant film layer, or a single-layer structure made by mixing any two or more (more than two) of EVA, POE, EPE, or PVB.

It should be noted that, in the embodiments of the present disclosure, the structure of the first encapsulant film layer 200 and the structure of the second encapsulant film layer 400 may be the same or different, and may be selected as desired. For example, in some embodiments, each of the first encapsulant film layer 200 and the second encapsulant film layer 400 may have a multi-layer composite structure. Materials of a plurality of layers forming the multi-layer composite structure may be the same or different, and the number of layers may be the same or different. In some embodiments, each of the first encapsulant film layer 200 and the second encapsulant film layer 400 may have a single-layer structure, and materials forming the single-layer structure may be the same or different. In some embodiments, one of the first encapsulant film layer 200 and the second encapsulant film layer 400 has a single-layer structure, and the other one of the first encapsulant film layer 200 and the second encapsulant film layer 400 has a multi-layer composite structure.

It should be additionally noted that, the materials of the first encapsulant film layer 200 and the second encapsulant film layer 400 may also be adjusted as desired, as long as they can play both bonding and buffering roles, and are not limited to the above limitations.

In some embodiments, the curved glass 100 has a thickness ranging from 3 mm to 5 mm. It should be understood that, the relatively large thickness of the curved glass 100 enables the curved photovoltaic module in the present embodiment to better withstand the impact energy from the direction of the curved glass 100, facilitating to improving the reliability of the entire curved photovoltaic module.

Optionally, the thickness of the curved glass 100 is 3 mm, 3.1 mm, 3.2 mm, 3.3 mm, 3.4 mm, 3.5 mm, 3.6 mm, 3.7 mm, 3.8 mm, 3.9 mm, 4 mm, 4.1 mm, 4.2 mm, 4.3 mm, 4.4 mm, 4.5 mm, 4.6 mm, 4.7 mm, 4.8 mm, or 4.9 mm. Of course, in other embodiments of the present disclosure, the thickness of the curved glass 100 may also be selected from any value between 3 mm and 5 mm as desired, and is not limited to the above examples.

Reference throughout this specification to “an embodiment”, “some embodiments”, “an illustrative embodiment”, “an example”, “a specific example”, or “some examples” means that a particular feature, structure, material, or characteristic described in connection with the embodiment or example is included in at least one embodiment or example of the present disclosure. In this specification, exemplary descriptions of aforesaid terms are not necessarily referring to the same embodiment or example. Further, the particular features, structures, materials, or characteristics may be combined in any suitable manner in one or more embodiments or examples.

Although embodiments of the present disclosure have been illustrated and described, it is conceivable for those skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A curved photovoltaic module, comprising:
a solar cell unit; and
curved glass and a curved back panel that are disposed at two sides of the solar cell unit, a first encapsulant film layer being arranged between the curved glass and the solar cell unit, and a second encapsulant film layer being arranged between the curved back panel and the solar cell unit, wherein:
the first encapsulant film layer has a thickness ranging from 0.8 mm to 2 mm; and
the second encapsulant film layer has a thickness ranging from 0.8 mm to 2 mm.

2. The curved photovoltaic module according to claim 1, wherein:
the curved back panel has a thickness ranging from 0.35 mm to 0.7 mm; and/or
the curved glass has a thickness ranging from 3 mm to 5 mm.

3. The curved photovoltaic module according to claim 1, wherein the curved back panel is a semi-rigid material layer, and is a polyethylene terephthalate (PET) layer or a glass fiber material layer.

4. The curved photovoltaic module according to claim 1, wherein the curved back panel comprises a main body layer and an encapsulation material layer arranged at each of both sides of the main body layer, the main body layer having a greater thickness than the encapsulation material layer.

5. The curved photovoltaic module according to claim 4, wherein:
the main body layer comprises an aluminum plate, and
the encapsulation material layer comprises a PET layer.

6. The curved photovoltaic module according to claim 1, wherein:
the first encapsulant film layer comprises at least one selected from the group consisting of an ethylene-vinyl acetate (EVA) encapsulant film, a polyolefin elastomer (POE) encapsulant film, a co-extruded ethylene-vinyl acetate and polyolefin elastomer (EPE) encapsulant film, and a polyvinyl butyral (PVB) encapsulant film; and/or
the second encapsulant film layer comprises at least one selected from the group consisting of an EVA encapsulant film, a POE encapsulant film, an EPE encapsulant film, and a PVB encapsulant film.

7. The curved photovoltaic module according to claim 1, wherein the solar cell unit comprises a plurality of solar cells, wherein each of the plurality of solar cells has a bending radius ranging from 25 mm to 200 mm.

8. The curved photovoltaic module according to claim 1, wherein:
a longitudinal projection of each of the curved back panel and the curved glass is a curve composed of a curve segment; or
a longitudinal projection of each of the curved back panel and the curved glass is an irregular curve composed of a curve segment and a straight segment,
wherein the curve segment is in an arc shape, wherein a ratio of an arc length to a corresponding chord length of the curve segment ranges from 1.03 to 1.67.

9. The curved photovoltaic module according to claim 1, wherein a longitudinal projection of each of the curved back panel and the curved glass is a curve composed of a plurality of curve segments connected in sequence,
wherein the curve segment is in an arc shape, wherein a ratio of an arc length to a corresponding chord length of the curve segment ranges from 1.03 to 1.67.

10. The curved photovoltaic module according to claim 9, wherein:
the longitudinal projection of the curved back panel comprises a plurality of first peaks and a plurality of first valleys that are arranged alternately; and
the longitudinal projection of the curved glass comprises a plurality of second peaks and a plurality of second valleys that are arranged alternately,
wherein the plurality of first peaks are aligned with the plurality of second peaks, respectively; and
wherein the plurality of first valleys are aligned with the plurality of second valleys, respectively.

11. The curved photovoltaic module according to claim 10, wherein:
each of the plurality of first peaks has the same curvature as each of the plurality of second peaks; and
each of the plurality of first valleys has the same curvature as each of the plurality of second valleys.

12. The curved photovoltaic module according to claim 10, wherein the solar cell unit comprises a plurality of solar cells electrically connected to each other, a part of each of the plurality of solar cells being located between a corresponding first peak of the plurality of first peaks and a corresponding second peak of the plurality of second peaks, and the other part of each of the plurality of solar cells being located between a corresponding first valley of the plurality of first valleys and a corresponding second valley of the plurality of second valleys.

13. The curved photovoltaic module according to claim 12, wherein:
a length of each of the plurality of solar cells is equal to a spacing between a highest point of the first peak and a lowest point of the first valley; and
a midline of each of the plurality of solar cells is coincident with an inflection line between the first peak and the first valley.

14. The curved photovoltaic module according to claim 12, wherein each of the plurality of solar cells has a bending radius ranging from 25 mm to 200 mm.

15. The curved photovoltaic module according to claim 1, wherein the thickness of the first encapsulant film layer is greater than that of the second encapsulant film layer.

16. The curved photovoltaic module according to claim 1, wherein:
both the first encapsulant film layer and the second encapsulant film layer have a multi-layer composite structure; or
both the first encapsulant film layer and the second encapsulant film layer have a single-layer structure; or
one of the first encapsulant film layer and the second encapsulant film layer has a single-layer structure, and the other one of the first encapsulant film layer and the second encapsulant film layer has a multi-layer composite structure.
